(19) United States
(12) Patent Application Publication
(10) Pub. No.: US 2012/0043576 A1
(43) Pub. Date: Feb. 23, 2012

(54) LED PACKAGE STRUCTURE

(75) Inventors: MIN-TSUN HSIEH, Hukou (TW); WEN-LIANG TSENG, Hukou (TW); LUNG-HSIN CHEN, Hukou (TW); CHIH-YUNG LIN, Hukou (TW); CHING-LIEN YEH, Hukou (TW); CHI-WEI LIAO, Hukou (TW); JIAN-SHIHN TSANG, Hukou Shiang (TW)

(73) Assignee: ADVANCED OPTOELECTRONIC TECHNOLOGY, INC., Hsinchu Hsien (TW)

(21) Appl. No.: 13/043,473

(22) Filed: Mar. 9, 2011

(30) Foreign Application Priority Data
Aug. 17, 2010 (CN) 201010255511.X

(51) Int. Cl. H01L 33/64

(52) U.S. Cl. 257/99; 257/E33.075

(57) ABSTRACT

An LED package structure includes a substrate with a concave groove therein, an LED die received in the concave groove, a heat conductive pillar, two electrically conductive pillars, a heat conductive plate, and two contact pads. The heat conductive pillar extends through the substrate and thermally connects with the LED die and the heat conductive plate. The electrically conductive pillars extend through substrate and electrically connect with the LED die, respectively. The electrically conductive pillars and the heat conductive pillar are spaced from each other. The contact pads respectively and electrically connect with the electrically conductive pillars. The contact pads are spaced from each other.

### BACKGROUND

1. Technical Field

The present disclosure relates to a light emitting diode (LED) package structure.

2. Description of Related Art

Presently, LEDs are preferred for use in non-emissive display devices than CCFLs (cold cathode fluorescent lamp) due to their high brightness, long lifespan, and wide color range. Especially, high-brightness, high-power LEDs are preferred for use over the past year.

However, high-brightness, high-power LEDs, while generating large amounts of light, also generate large amounts of heat which can cause thermal degradation of the characteristics of the LEDs and reduce the overall lifespan of the LEDs. A typical LED package structure includes an LED die adhered on a silicon substrate. The silicon substrate generally has good processability but a relatively poor heat conductivity. The LED package structure uses the silicon substrate to transfer the heat. Unfortunately, the silicon substrate is not efficient enough to solve the thermal degradation problem of the LED.

What is needed, therefore, is an LED package structure which can overcome the limitations described.

### BRIEF DESCRIPTION OF THE DRAWINGS

FIG. 1 is a cross-sectional view of an LED package structure according to a first embodiment of the present disclosure.

FIG. 2 is a cross-sectional view of an LED package structure according to a second embodiment of the present disclosure.

FIG. 3 is a cross-sectional view of an LED package structure according to a third embodiment of the present disclosure.

FIG. 4 is a cross-sectional view of an LED package structure according to a fourth embodiment of the present disclosure.

FIG. 5 is a cross-sectional view of an LED package structure according to a fifth embodiment of the present disclosure.

FIG. 6 is a cross-sectional view of an LED package structure according to a sixth embodiment of the present disclosure.

### DETAILED DESCRIPTION

Embodiments of the disclosure will now be described in detail with reference to the accompanying drawings.

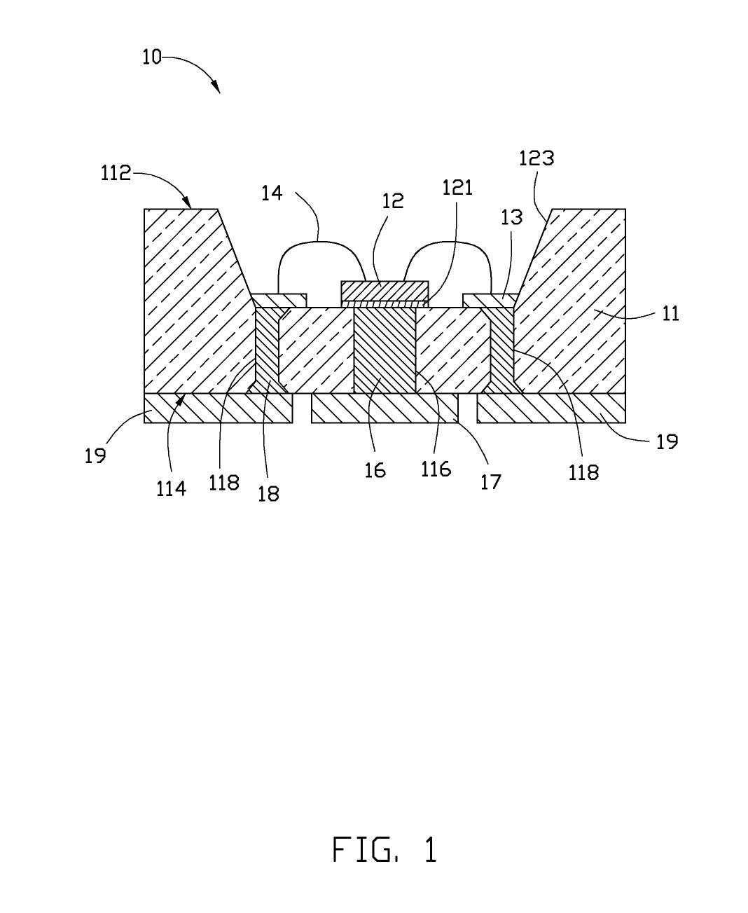

Referring to FIG. 1, an LED package structure 10 in accordance with a first embodiment of the disclosure is illustrated. The LED package structure 10 includes a substrate 11, an LED die 12, two electrodes 13, and two metal wires 14 electrically connecting the LED die 12 with the electrodes 13.

The substrate 11 is a part of a wafer before the LED package structure 10 is made. The LED package structure 10 is packaged before the wafer is cut into pieces wherein the substrate 11 is obtained from one of the pieces. The wafer and accordingly the substrate 11 are made of silicon. The substrate 11 has a first surface 112 and a second surface 114 opposite to the first surface 112. The substrate 11 defines a concave groove 123 in the first surface 112 for receiving the LED die 12 therein. The substrate 11 defines a central opening 116 and two lateral through holes 118 by E-beam or other energy beam. The through holes 118 and the central opening 116 are spaced from each other. The central opening 116 and the through holes 118 are defined through the first surface 112 and the second surface 114. A heat conductive pillar 16 is formed in the central opening 116 and two electrically conductive pillars 18 are formed in the through holes 118 by Physical Vapor Deposition (PVD) or other physical deposition method.

The LED die 12 is arranged in the concave groove 123 to thermally connect a top of the heat conductive pillar 16. The LED die 12 is made of Group III-V semiconductor compound or Group II-VI semiconductor compound. In this embodiment, the LED die 12 is a horizontal type LED. A eutectic layer 121 is formed between the LED die 12 and the heat conductive pillar 16. The eutectic layer 121 is formed by two metal layers (not shown) respectively connecting the heat conductive pillar 16 with bottom of the LED die 12 and joined together by eutectic bonding. The eutectic layer 121 contains at least one selected from Au, Sn, In, Al, Ag, Bi, Be or an alloy thereof.

Each of the electrodes 13 is mounted on the substrate 11 and electrically connects with the corresponding electrically conductive pillar 18. In this embodiment, tops of the electrically conductive pillars 18 are exposed to the concave groove 123, and the electrodes 13 are disposed at a bottom of the concave groove 123. A heat conductive plate 17 is attached to the second surface 114 of the substrate 11 and arranged under the heat conductive pillar 16. The heat conductive plate 17 and the heat conductive pillar 16 can be made of copper. The heat conductive pillar 16 connects the LED die 12 with the heat conductive plate 17 to conduct heat from the LED die 12 to the heat conductive plate 17. Two contact pads 19 are attached to the second surface 114 of the substrate 11 and electrically connect with the electrically conductive pillars 18, respectively. In this embodiment, the contact pads 19 and the heat conductive plate 17 are spaced from each other.

When the LED package structure 10 works, heat generated from the LED die 12 can be rapidly conducted to the heat conductive plate 17 through the heat conductive pillar 16 whereby the heat dissipating efficiency of the LED package structure 10 is increased. Thus, the heat is more quickly and efficiently transported away from the LED die 12 and a lifespan of the LED package structure 10 is increased.

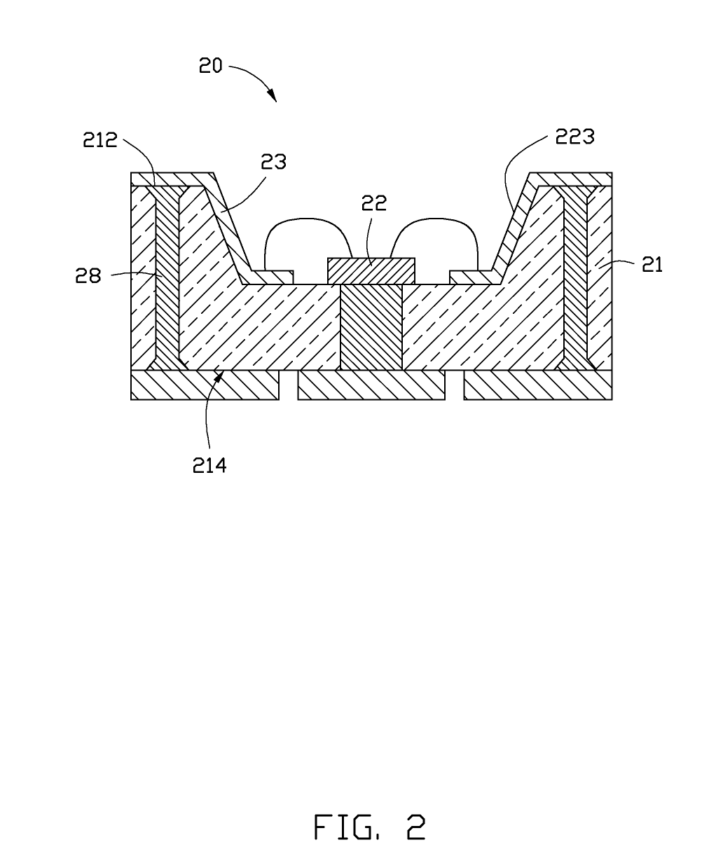

Referring to FIG. 2, an LED package structure 20 in accordance with a second embodiment includes a substrate 21, an LED die 22, two electrodes 23 electrically connecting with the LED die 22, and two electrically conductive pillars 28 respectively connecting to the electrodes 23. The substrate 21 has a first surface 212 and a second surface 214 opposite to the first surface 212. A concave groove 223 is defined in the first surface 212 for receiving the LED die 22 therein. The difference of the LED package structure 20 from the LED package structure 10 of the first embodiment is that the electrically conductive pillars 28 are arranged apart from the concave groove 223. Each of the electrodes 23 has a bottom part mounted on the first surface 212 defining a bottom of the concave groove 223, a top part mounted to the first surface 212 to electrically connect to the electrically conductive pillar 28, and a middle part extending over an inclined portion of the top first surface 212 defining an inclined circumferential periphery of the concave groove 223.

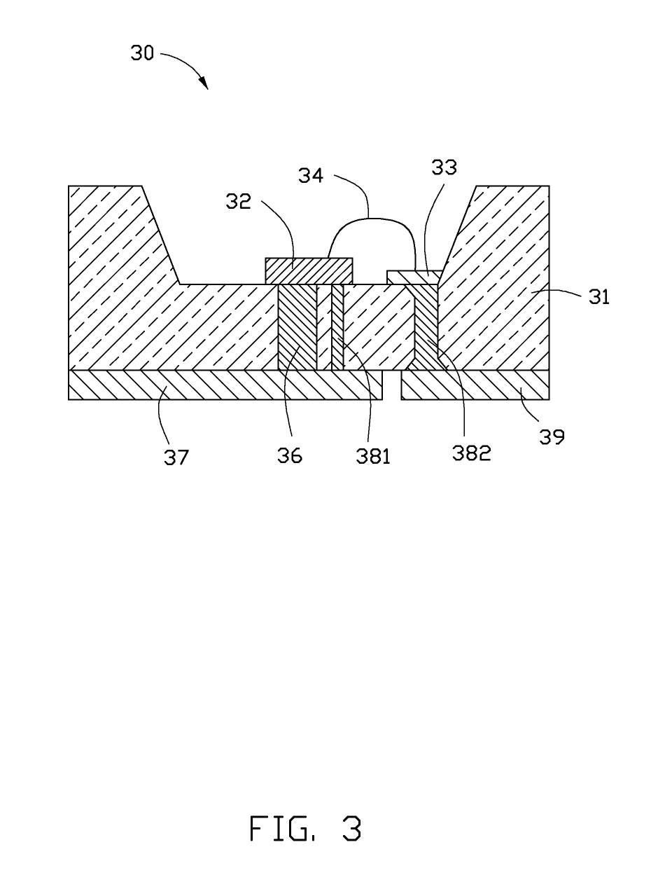

Referring to FIG. 3, an LED package structure 30 in accordance with a third embodiment includes a substrate 31 and an LED die 32. A first electrically conductive pillar 381, a second electrically conductive pillar 382, and a heat conductive pillar 36 are formed in the substrate 31. A heat conductive plate 37 and a contact pad 39 are attached to a bottom of the substrate 31. The difference of the LED package 30 from the LED package structure 10 of the first embodiment is that the LED die 32 is a vertical type LED. The LED die 32 has a top electrode (not labeled) connecting an electrode 33 by a metal wire 34, and a bottom electrode (not labeled) directly connecting the first electrically conductive pillar 381. The second electrically conductive pillar 382 electrically connects the electrode 33 with the contact pad 39. The heat conductive plate 37 electrically connects the first electrically conductive pillar 381.

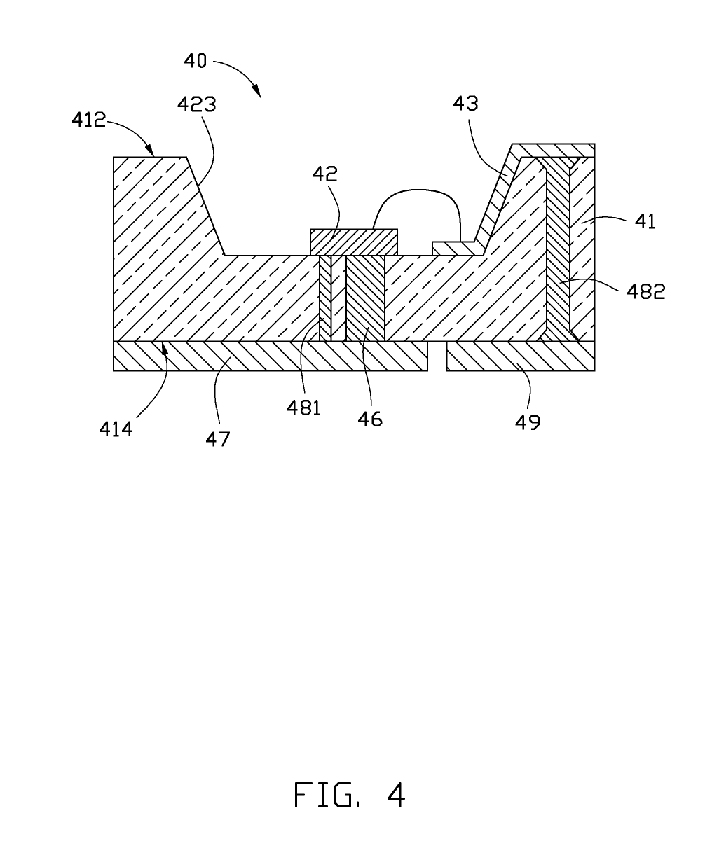

Referring to FIG. 4, an LED package structure 40 in accordance with a fourth embodiment includes a substrate 41 and an LED die 42. The substrate 41 has a first surface 412 and a second surface 414 opposite to the first surface 412. A concave groove 423 is defined in the first surface 412 of the substrate 41 for receiving the LED die 42 therein. A first electrically conductive pillar 481, a second electrically conductive pillar 482, and a heat conductive pillar 46 are formed in the substrate 41. The difference of the LED package structure 40 from the LED package structure 30 of the third embodiment is that the second electrically conductive pillar 482 is arranged apart from the concave groove 423. An electrode 43 is similar to the electrode 23 of the second embodiment. The electrode 43 extends from a bottom of the concave groove 423 to a top end of the second electrically conductive pillar 482.

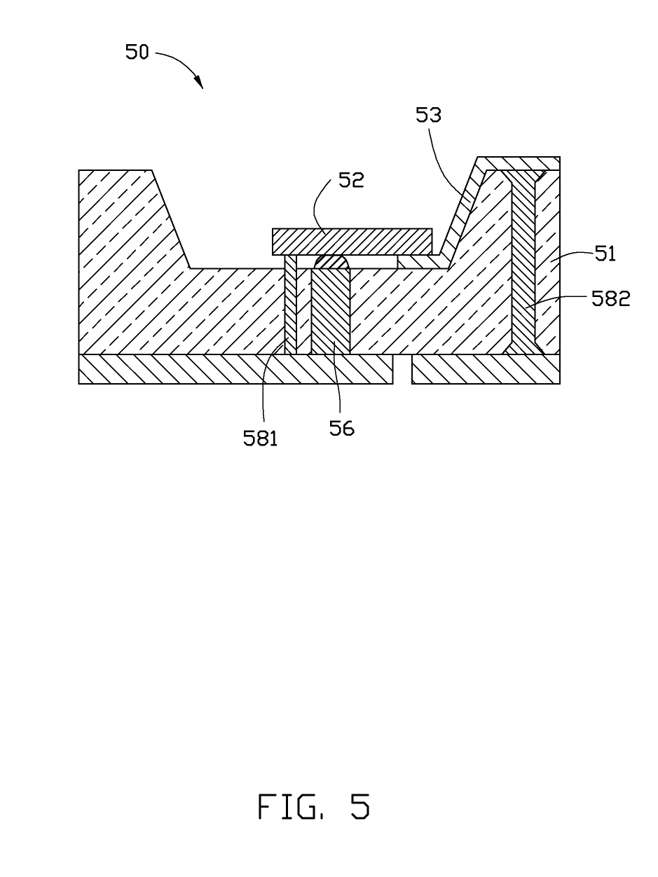

Referring to FIG. 5, an LED package structure 50 in accordance with a fifth embodiment includes a substrate 51 and an LED die 52. A first electrically conductive pillar 581, a second electrically conductive pillar 582, and a heat conductive pillar 56 are formed in the substrate 51. An electrode 53 is mounted on the substrate 51 and electrically connected with the second electrically conductive pillar 582. The difference of the LED package structure 50 from the LED package structure 40 of the fourth embodiment is that the LED die 52 is a flip chip bonded to the first electrically conductive pillar 581 and the electrode 53.

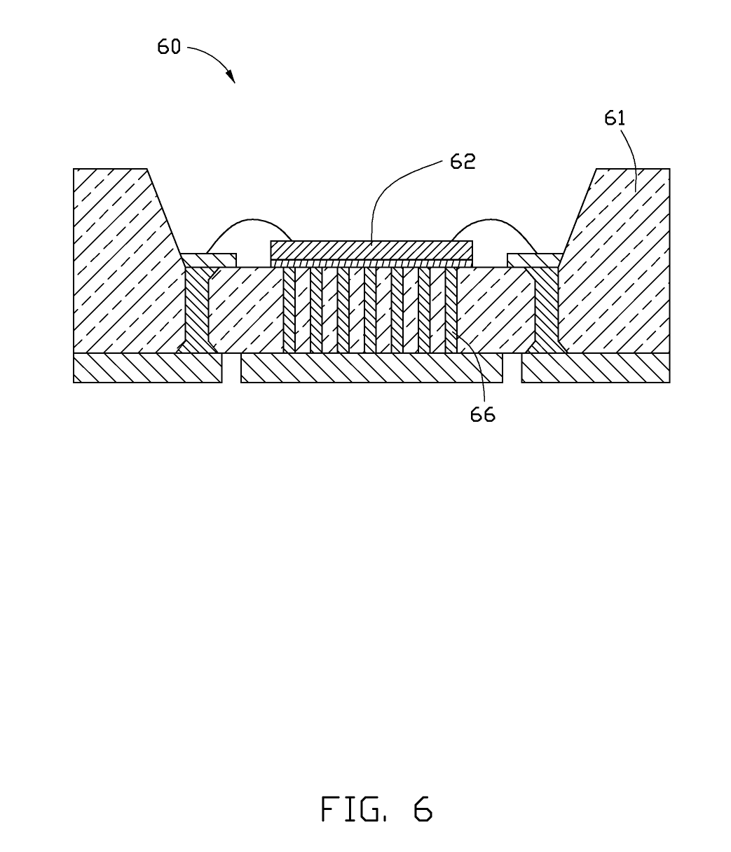

Referring to FIG. 6, an LED package structure 60 in accordance with a sixth embodiment includes a substrate 61 and an LED die 62. The difference of the LED package structure 60 from the LED package structure 10 of the first embodiment is that the LED package structure 60 includes a plurality of heat conductive pillars 66 arranged in the substrate 61 and under the LED die 62 to thermally connect to the LED die 62.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) package structure, comprising:
a substrate comprising a first surface and a second surface opposite to the first surface, the substrate defining a concave groove in the first surface;
an LED die received in the concave groove of the substrate;
a heat conductive pillar extending through the substrate and thermally connected to the LED die;
a heat conductive plate attached to the second surface of the substrate and thermally connected to the heat conductive pillar;
two electrically conductive pillars extending through the substrate and electrically connecting with the LED die, respectively, the electrically conductive pillars and the heat conductive pillar spaced from each other; and
two contact pads respectively electrically connecting with the electrically conductive pillars, the contact pads spaced from each other.

2. The LED package structure of claim 1, wherein the substrate is obtained by cutting a wafer.

3. The LED package structure of claim 2, wherein the substrate is made of silicon.

4. The LED package structure of claim 1, wherein at least one of the electrically conductive pillars is arranged apart from the concave groove, an electrode mounted on the substrate electrically connecting with the at least one of the electrically conductive pillars.

5. The LED package structure of claim 4, wherein the electrode has a bottom part mounted on the first surface defining a bottom of the concave groove, a top part mounted to the first surface to electrically connect to the electrically conductive pillar, and a middle part covering the first surface defining an inclined circumferential surface of the concave groove.

6. The LED package structure of claim 1, further comprising a eutectic layer formed between the LED die and the heat conductive pillar.

7. The LED package structure of claim 1, wherein the LED die is a vertical type LED.

8. The LED package structure of claim 1, wherein the LED die is a flip chip bonded to the two electrically conductive pillars.

9. The LED package structure of claim 1, wherein the heat conductive pillar is connected with one of the contact pads.

10. The LED package structure of claim 1, wherein an amount of the heat conductive pillar is at least two.

11. A light emitting diode (LED) package structure, comprising:
a substrate with a first surface and a second surface opposite to the first surface, the substrate defining a concave groove in the first surface;
an LED die received in the concave groove of the substrate;
a heat conductive pillar extending through the substrate and thermally connecting with the LED die;
a first electrically conductive pillar extending through the substrate and electrically connecting with the LED die; and
a second electrically conductive pillar extending through the substrate apart from the concave groove, an electrode electrically connecting with a top of the second electrically conductive pillar and the LED die.
